(19) United States
(12) Patent Application Publication
(10) Pub. No.: US 2026/0221860 A1
(43) Pub. Date: Jul. 30, 2026

(54) METHOD AND SYSTEM FOR CONTROLLING HYBRID MODULAR DIRECT CURRENT TRANSFORMER BASED ON LOAD-CURRENT FEEDFORWARD

(71) Applicant: SHANDONG UNIVERSITY, Jinan (CN)

(72) Inventors: Alian CHEN, Jinan (CN); Wei WANG, Jinan (CN); Tong LIU, Jinan (CN); Shijie CHENG, Jinan (CN)

(21) Appl. No.: 19/457,350

(22) Filed: Jan. 23, 2026

(30) Foreign Application Priority Data
Jan. 24, 2025 (CN) 2025101192312

(51) Int. Cl. H02M 1/00; H02M 3/335; H02P 13/00; H03K 7/08

(52) U.S. Cl. CPC H02M 1/0022; H02M 1/0009; H02M 1/0025; H02M 3/33515; H02P 13/00; H03K 7/08

(57) ABSTRACT

A method for controlling a hybrid modular direct current transformer (HMDCT) based on load-current feedforward featuring fast dynamic response, may include: acquiring corresponding measured voltage and current values of the HMDCT according to a selected control mode; inputting a difference between the measured voltage value and its reference value to a PI controller to obtain an error compensation component; constructing a transfer function of the load-current feedforward path in real time; constructing an improved feedforward control strategy based on the measured current value, the error compensation component, and the transfer function of the load-current feedforward path, and calculating a reference value of the PS-DAB output current in real time; and calculating an optimal phase-shift ratio of the PS-DAB according to the reference value of the output current of the PS-DAB, and generating modulated PWM signals to control the HMDCT in the selected mode.

### CROSS-REFERENCE TO RELATED APPLICATIONS

The present invention claims priority benefits to Chinese Patent Application No. 202510119231.2, entitled “METHOD AND SYSTEM FOR CONTROLLING HYBRID MODULAR DIRECT CURRENT TRANSFORMER BASED ON LOAD-CURRENT FEEDFORWARD”, filed on Jan. 24, 2025, with the China National Intellectual Property Administration, which is incorporated herein by reference in its entirety and constitutes a part of the present invention for all purposes.

### TECHNICAL FIELD

The present invention relates to the technical field of dynamic performance improvement and control of direct current (DC) transformers, and specifically to a method and system for controlling a hybrid modular DC transformer based on load-current feedforward.

### BACKGROUND

With the rapid growth of various renewable energy, loads, and energy storage, DC transformers have become the key hub and core equipment in DC distribution systems, which perform important functions such as bidirectional power conversion, transmission, and electrical isolation between ports and DC busbars. Their performance directly affects system operating efficiency and the utilization rate of renewable energy.

In recent years, to further improve the performance of DC transformers, scholars have proposed the concept of “hybrid modular DC transformers (HMDCT)”, which has attracted widespread attention from academia and industry. A series of similar variations have also been developed based on this concept. Compared with traditional input series output parallel (ISOP) DC transformers composed only of phase-shift dual active bridge (PS-DAB) converter submodules (hereinafter referred to as PS-DAB), HMDCT uses series resonant dual active bridge (SR-DAB) converter submodules (hereinafter referred to as SR-DAB) to replace some of the PS-DABs in traditional DC transformers, which not only significantly improves the overall conversion efficiency of the DC transformers but also retains the advantages of flexible and controllable voltages/currents provided by PS-DAB for traditional DC transformers.

Although HMDCT offers significant advantages in steady-state performance such as efficiency and controllability, its dynamic performance is inferior to that of the DC transformers composed only of PS-DAB. The reason for this is that SR-DAB works in a series resonant mode and dominates the total transmission power of HMDCT, causing HMDCT to exhibit slow dynamic characteristics similar to those of SR-DAB. When the output side is connected to a pulsating power load or power supply, slow dynamic characteristics imply larger ripple and overshoot, which may interfere with other devices or necessitate larger capacity filter capacitors for the system, thereby increasing costs and shortening system lifespan. The above problems severely limit the further replacement of traditional DC transformers by HMDCT in fields such as microgrids, renewable energy power generation, and DC traction, and further restrict the improvement in performance of DC transformers in these fields. Therefore, at present, the dynamic performance of HMDCT urgently needs to be improved.

### SUMMARY

To solve the above problems, the present invention provides a method and system for controlling a HMDCT based on load-current feedforward, which can improve the dynamic performance of the HMDCT, quickly respond to a change in a load current or power, and maintain excellent stability of an output voltage even during a sudden change in a power flow direction.

According to some examples, the present invention adopts the following technical solution.

A method for controlling a HMDCT based on load-current feedforward, may be quickly responding to a change in a load current for the HMDCT that at least includes one PS-DAB and one SR-DAB, wherein specific steps of the method are as follows:
acquiring a corresponding measured voltage value and measured current value of the HMDCT according to a currently selected control mode;
calculating a difference between the measured voltage value and a voltage reference value, using the difference as a control error, and inputting the difference into a proportional-integral (PI) controller, to obtain an error compensation component;
constructing a transfer function of a load-current feedforward path in real time according to a hardware parameter and the measured voltage value of the HMDCT;
constructing an improved feedforward control strategy based on the measured current value, the error compensation component, and the transfer function of the load-current feedforward path, and calculating a reference value of an output current of the PS-DAB in real time; and
calculating an optimal phase shift ratio of the PS-DAB according to the reference value of the output current of the PS-DAB;
modulating to generate PWM signals according to the optimal phase shift ratio obtained through calculation, and inputting the wave into the HMDCT; and
controlling and driving, based on the PWM signals, switching components in the HMDCT to perform corresponding switching actions, thereby controlling the HMDCT to quickly respond to the change in the load current in the currently selected control mode.

According to some examples, the present invention adopts the following technical solution.

A system for controlling a HMDCT based on load-current feedforward, may be quickly responding to a change in a load current for the HMDCT that at least includes one PS-DAB and one SR-DAB, including:
a data real-time acquisition module, configured to: acquire a corresponding measured voltage value and measured current value of the HMDCT according to a currently selected control mode;
an error compensation calculation module, configured to: calculate a difference between the measured voltage value and a voltage reference value, use the difference as a control error, and input the difference into a PI controller, to obtain an error compensation component;
a transfer function construction module, configured to: construct a transfer function of a load-current feedforward path in real time according to a hardware parameter and the measured voltage value of the HMDCT;
a current reference calculation module, configured to: construct an improved feedforward control strategy based on the measured current value, the error compensation component, and the transfer function of the load-current feedforward path, and calculate a reference value of an output current of the PS-DAB in real time; and
a PWM signals generation module, configured to: calculate an optimal phase shift ratio of the PS-DAB according to the reference value of the output current of the PS-DAB, modulate to generate PWM signals according to the optimal phase shift ratio obtained through calculation, and input the wave into the HMDCT; and
controlling and driving, based on the PWM signals, switching components in the HMDCT to perform corresponding switching actions, thereby controlling the HMDCT to quickly respond to the change in the load current in the currently selected control mode.

According to some examples, the present invention adopts the following technical solution:

A computer program product, including a computer program, wherein when the computer program is executed by a processor, causing the processor to implement the method for controlling the HMDCT based on the load-current feedforward according to the above-mentioned solutions.

According to some examples, the present invention adopts the following technical solution.

A non-transitory computer-readable storage medium, and the non-transitory computer-readable storage medium is configured to store a computer instruction, wherein when the computer instruction is executed by a processor, causing the processor to implement the method for controlling the HMDCT based on the load-current feedforward according to the above-mentioned solutions.

According to some examples, the present invention adopts the following technical solution.

An electronic device, including: a processor, a memory, and a computer program, wherein the processor is connected to the memory, the computer program is stored in the memory, and when the electronic device is operated, the processor executes the computer program stored in the memory, to enable the electronic device to execute and implement the method for controlling the HMDCT based on the load-current feedforward according to the above-mentioned solutions.

Compared with the prior art, the beneficial effects of the present invention are as follows:

According to the present invention, by designing a rationally improved load-current feedforward method, a linear “control input-output voltage” equivalent control loop is established, which can approximately eliminate the influence of load-current disturbances on the control loop, allowing the output voltage to quickly recover to a steady-state value within several switching cycles after a load step change, while also naturally adapting to changes in the power flow direction. By slightly adjusting the control parameters, this method can flexibly switch from the low-voltage side voltage control mode of the HMDCT to the high-voltage side voltage control mode.

Furthermore, according to the present invention, complex virtual state variable peak measurement and estimation circuits or complex state observers are not required, which can be implemented simply by adding one second-order filter (that is, the transfer function of the load-current feedforward path) to a traditional PI control and has characteristics of simple structures, less calculation, and strong engineering practicability.

### BRIEF DESCRIPTION OF THE DRAWINGS

The accompanying drawings of the specification, which constitute a part of the present invention, provide further understanding of the present invention. The schematic examples of the present invention and description thereof are intended to explain the present invention and are not intended to constitute an improper limitation to the present invention.

FIG. 1A is an implementation flowchart corresponding to a low-voltage side voltage control mode of an HMDCT in Example 1.

FIG. 1B is an implementation flowchart corresponding to a high-voltage side voltage control mode of the HMDCT in Example 1.

FIG. 2 is a schematic topological diagram of the HMDCT of Example 1.

FIG. 3A is an implementation block diagram of the HMDCT in a low-voltage side voltage control mode in Example 1.

FIG. 3B is a block diagram of an equivalent transfer function of the HMDCT in the low-voltage side voltage control mode in Example 1.

FIG. 3C is a form block diagram of an equivalent transfer function without a load-current disturbance of the HMDCT in the low-voltage side voltage control mode in Example 1.

FIG. 4A is an implementation block diagram of the HMDCT in a high-voltage side voltage control mode in Example 1.

FIG. 4B is a block diagram of an equivalent transfer function of the HMDCT in the high-voltage side voltage control mode in Example 1.

FIG. 4C is a form block diagram of an equivalent transfer function without the load-current disturbance of the HMDCT in the high-voltage side voltage control mode in Example 1.

FIG. 5A is a chart of simulation waveform comparison between a low-voltage side output voltage of the HMDCT in the low-voltage side output voltage control mode and those of traditional “only PI” and “PI+load-current feedforward” methods in Example 1.

FIG. 5B is a chart of simulation waveform comparison between a phase shift ratio of a PS-DAB of the HMDCT in the low-voltage side output voltage control mode and those of traditional “only PI” and “PI+load-current feedforward” methods in Example 1.

FIG. 5C is a chart of simulation waveform comparison between a low-voltage side output current of the HMDCT in the low-voltage side output voltage control mode and those of traditional “only PI” and “PI+load-current feedforward” methods in Example 1.

FIG. 6A is a chart of simulation waveform comparison between the low-voltage side output voltage of the HMDCT in the low-voltage side output voltage control mode when a load current (power flow) direction reverses and those of traditional “only PI” and “PI+load-current feedforward” methods in Example 1.

FIG. 6B is a chart of simulation waveform comparison between the phase shift ratio of the PS-DAB of the HMDCT in the low-voltage side output voltage control mode when the load-current (power flow) direction reverses and those of traditional “only PI” and “PI+load-current feedforward” methods in Example 1.

FIG. 6C is a chart of simulation waveform comparison between the low-voltage side output current of the HMDCT in the low-voltage side output voltage control mode when the load-current (power flow) direction reverses and those of traditional “only PI” and “PI+load-current feedforward” methods in Example 1.

FIG. 7A is a chart of simulation waveform comparison between a high-voltage side output voltage of the HMDCT in the high-voltage side output voltage control mode and those of traditional “only PI” and “PI+load-current feedforward” methods in Example 1.

FIG. 7B is a chart of simulation waveform comparison between a phase shift ratio of a PS-DAB of the HMDCT in the high-voltage side output voltage control mode and those of traditional “only PI” and “PI+load-current feedforward” methods in Example 1.

FIG. 7C is a chart of simulation waveform comparison between a high-voltage side output current of the HMDCT in the high-voltage side output voltage control mode and those of traditional “only PI” and “PI+load-current feedforward” methods in Example 1.

### DETAILED DESCRIPTION

The present invention is further described with reference to the accompanying drawings and examples.

It should be noted that the following detailed description is exemplary and aims to further describe the present invention. Unless otherwise stated, all technical and scientific terms used herein have the same meanings as those commonly understood by those skilled in the art of the present invention.

It should be noted that the terms used herein are only for describing the examples rather than for limiting the exemplary examples of the present invention. As used herein, the singular form is also intended to include the plural form unless otherwise indicated obviously from the context. Furthermore, it should be further understood that the terms “include” and/or “comprise” used in this specification specify the presence of features, steps, operations, devices, assemblies and/or a combination thereof.

### Example 1

The present example of the present invention provides a method for controlling a HMDCT based on load-current feedforward, may be quickly responding to a change in a load current for the HMDCT that at least includes one PS-DAB and one SR-DAB, where specific control steps are as follows:
Step S1: acquiring a corresponding measured voltage value and measured current value of the HMDCT according to a currently selected control mode;
Step S2: calculating a difference between the measured voltage value and a voltage reference value, using the difference as a control error, and inputting the difference into a PI controller, to obtain an error compensation component;
Step S3: constructing a transfer function of a load-current feedforward path in real time according to a hardware parameter and the measured voltage value of the HMDCT;
Step S4: constructing an improved feedforward control strategy based on the measured current value, the error compensation component, and the transfer function of the load-current feedforward path, and calculating a reference value of an output current of the PS-DAB in real time;
Step S5: calculating an optimal phase shift ratio of the PS-DAB according to the reference value of the output current of the PS-DAB; and
Step S6: modulating to generate PWM signals according to the optimal phase shift ratio obtained through calculation, and inputting the wave into the HMDCT; and controlling and driving, based on the PWM signals, switching components in the HMDCT to perform corresponding switching actions, thereby controlling the HMDCT to quickly respond to the change in the load current in the currently selected control mode.

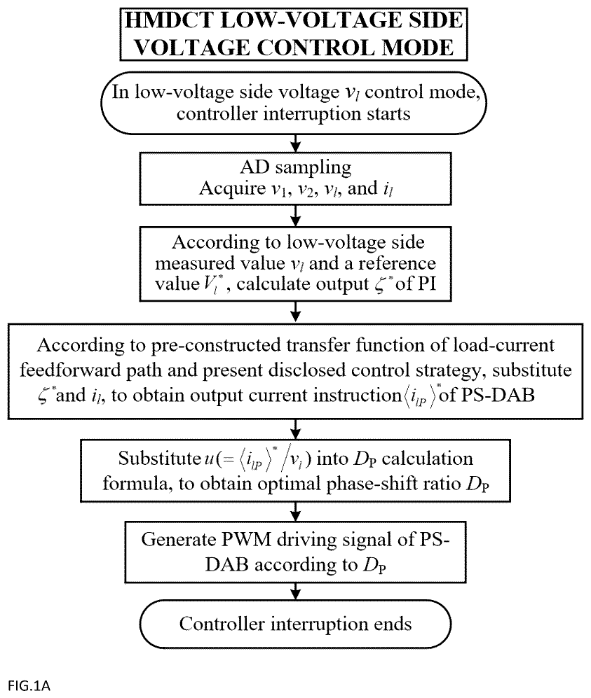

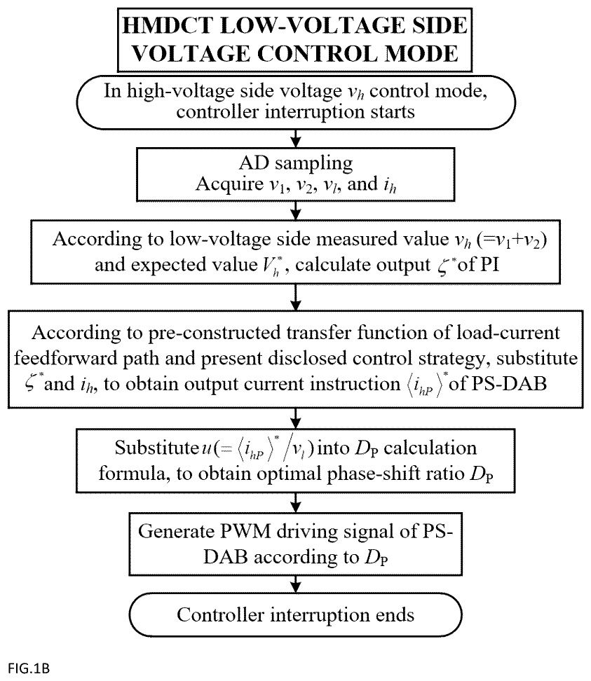

As an example, the method for controlling the HMDCT based on the load-current feedforward of the present invention may control the HMDCT cyclically, which can naturally adapt to a change in a power flow direction and rapidly respond to the change in the load current, and maintain excellent stability and dynamic performance of the output voltage. As shown in FIG. 1A and FIG. 1B, specific implementation processes are as follows:

Step 1: when one control cycle starts, acquiring a corresponding measured voltage value and measured current value of the HMDCT according to a currently selected control mode.

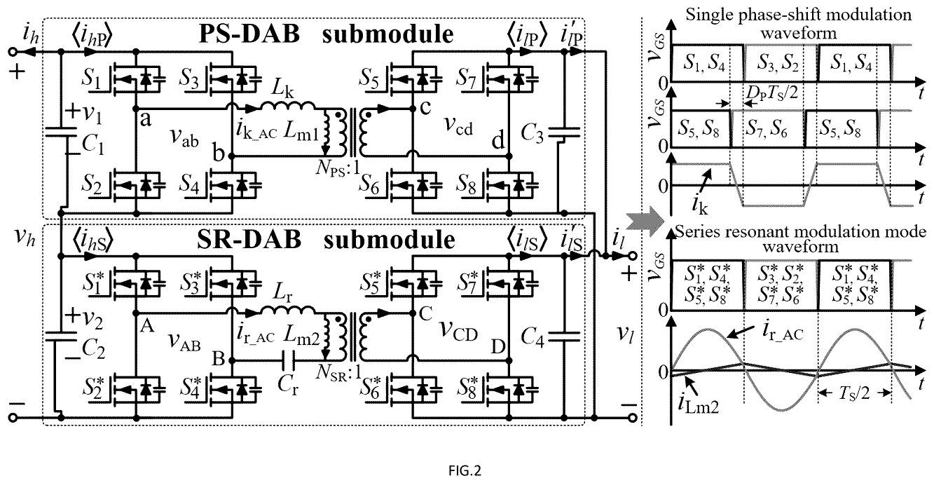

Generally, the HMDCT may include a plurality of PS-DABs and SR-DABs. In the present example, the plurality of PS-DABs and SR-DABs in the HMDCT are equivalent to one PS-DAB and one SR-DAB respectively, thereby obtaining a topological structural diagram of the HMDCT shown in FIG. 2. The obtained equivalent PS-DAB and SR-DAB are connected in an ISOP manner. On a high-voltage side of the HMDCT, various submodule ports are connected in series, and the side where the submodule ports are connected in series is hereinafter referred to as the high-voltage side of the submodule. On a low-voltage side of the HMDCT, various submodule ports are connected in parallel, and the side where the submodule ports are connected in parallel is hereinafter referred to as the low-voltage side of the submodule. The HMDCT supports two control modes: a low-voltage side voltage control mode and a high-voltage side voltage control mode. The low-voltage side voltage control mode takes the high-voltage side as an input and the low-voltage side as an output, while the high-voltage side voltage control mode takes the low-voltage side as an input and the high-voltage side as an output.

If the HMDCT is required to work in the low-voltage side voltage control mode, a high-voltage side voltage v₁ of the PS-DAB, a high-voltage side voltage v₂ of the SR-DAB, a low-voltage side output voltage vₗ of the HMDCT, and a low-voltage side load current iₗ of the HMDCT are measured.

If the HMDCT is required to work in the high-voltage side voltage control mode, a high-voltage side voltage v₁ of the PS-DAB, a high-voltage side voltage v₂ of the SR-DAB, a low-voltage side input voltage vₗ of the HMDCT, and a high-voltage side load current iₕ of the HMDCT are measured.

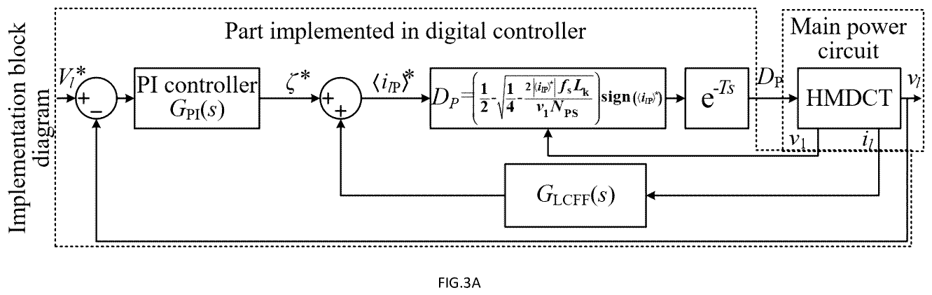

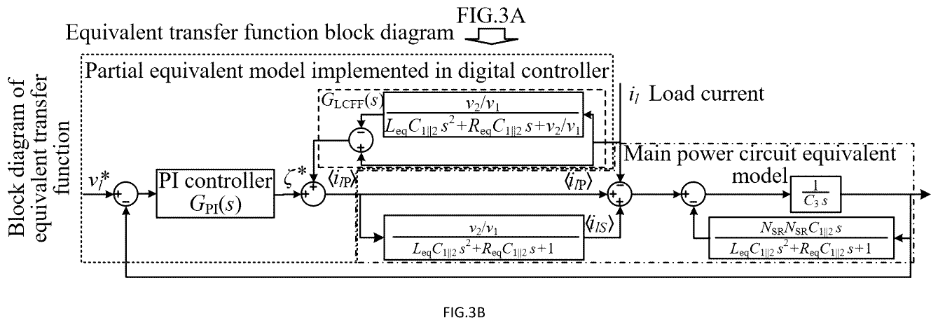

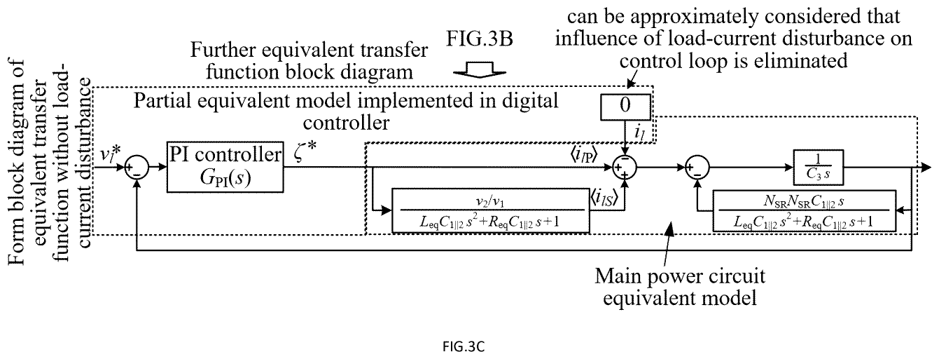

Step 2: if the HMDCT is required to work in the low-voltage side voltage control mode, a quantity that is input to the PI controller GPI(s) is a difference (V*ᵢ−vₗ) between a low-voltage side measured voltage value vₗ and a reference value V*ᵢ thereof, as shown in FIG. 3.

Parameters of the PI controller are designed by controlling a first-order integral element (1/((C₃+C₄)s)) formed by connecting low-voltage side capacitors of all submodules in parallel. A magnitude margin and a phase margin can be designed to be approximately 10 dB and 65° respectively. An output of the PI controller is ζ*, that is, an error compensation component of a reference output current of the PS-DAB, which is represented by a formula as follows:

$$ζ * ( s ) = {G}_{PI} ( s ) ( {V}_{l}^{*} ( s ) - {v}_{l} ( s ) ) ; \qquad ( 1 )$$

Wherein, s is a complex frequency variable in the transfer function, G_{PI}(s) represents the PI controller, and vₗ and

$${V}_{l}^{*}$$

are the low-voltage side measured voltage value and the reference value respectively.

If the HMDCT is required to work in the high-voltage side voltage control mode, a quantity that is input to the PI controller GPI(s) is a difference

$$( {V}_{h}^{*} - {v}_{1} - {v}_{2} )$$

between a high-voltage side measured voltage value vₕ=(v₁+v₂) and a reference value

$${V}_{h}^{*}$$

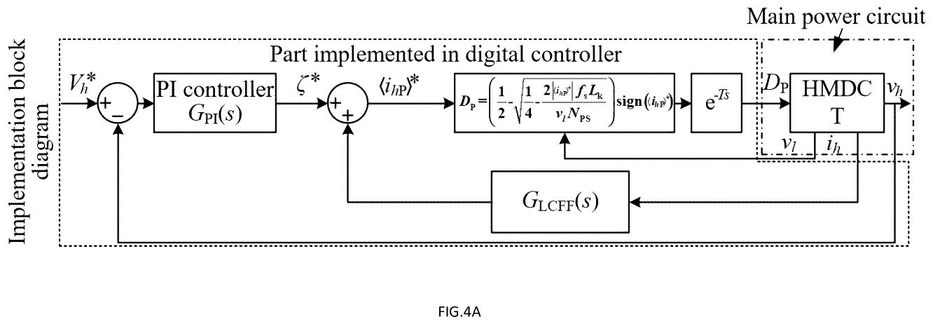

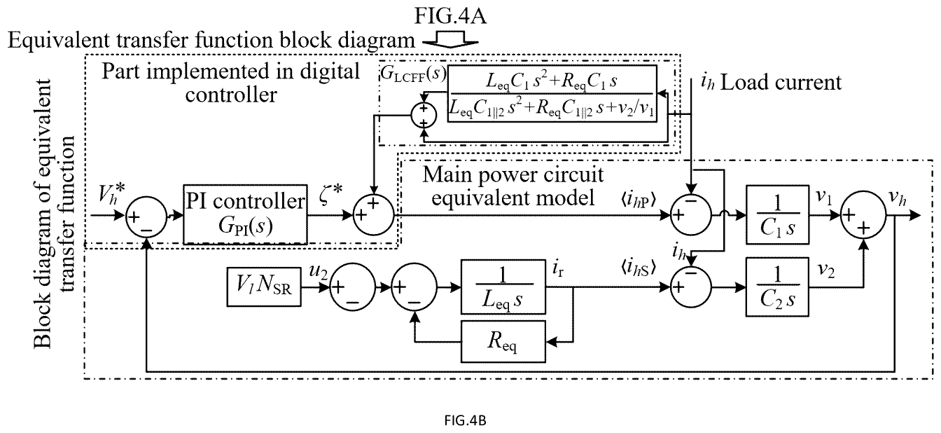

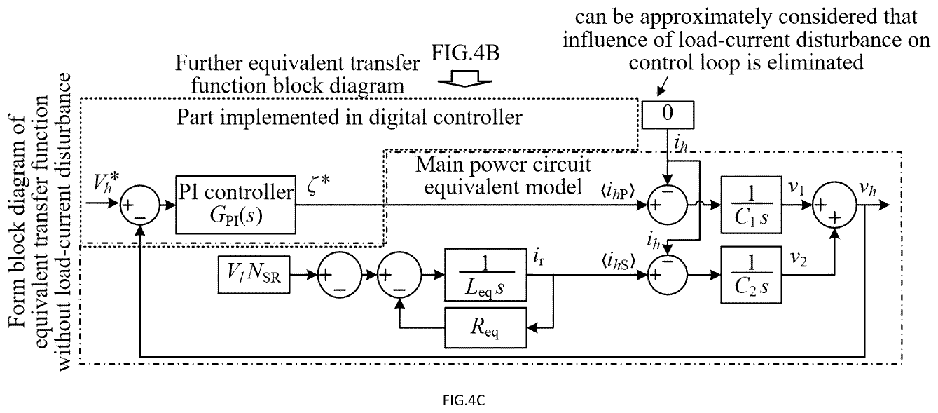

thereof, as shown in FIG. 4.

Parameters of the PI controller are designed by only controlling a first-order integral element (1/(C₁s)) formed by low-voltage side capacitors of the PS-DAB module. A magnitude margin and a phase margin can be designed to be approximately 10 dB and 65° respectively. An output of the PI controller is ζ*, that is, an error compensation component of a reference output current of the PS-DAB, which is represented by a formula as follows:

$$ζ * ( s ) = {G}_{PI} ( s ) ( {V}_{h}^{*} ( s ) - {v}_{h} ( s ) ) . \qquad ( 2 )$$

Step 3: constructing the transfer function of the load-current feedforward path based on a transfer function model of the HMDCT, the hardware parameter of the HMDCT, and input and output voltages of the HMDCT.

As shown in FIG. 3B, the transfer function G_{LCFF}(S) of the load-current feedforward path in the low-voltage side voltage control mode of the HMDCT is as follows:

$${G}_{LCFF} ( s ) = 1 - \frac{{v}_{2} / {v}_{1}}{{L}_{eq} {C}_{1 ‖ 2} {s}^{2} + {R}_{eq} {C}_{1 ‖ 2} s + 1 + {v}_{2} / {v}_{1}} ; \qquad ( 3 )$$

wherein, v₁ and v₂ are a high-voltage side measured voltage value of the PS-DAB and a high-voltage side measured voltage value of the SR-DAB in a current working state of the HMDCT, C_{1∥2} is the sum of capacitance values of capacitors C₁ and C₂, and L_{eq} and R_{eq} are equivalent DC inductance and resistance respectively, which are represented by formulas as follows:

$${L}_{eq} = \frac{{π}^{2} {L}_{r}}{4} , {R}_{eq} = \frac{{π}^{2} {R}_{loss}}{8} ; \qquad ( 4 )$$

wherein, Lᵣ is a resonant inductance value of the SR-DAB, and Rₗₒₛₛ represents the sum of on-resistances of a resonant cavity, a transformer, and an MOSFET.

Since the transfer function G_{LCFF}(S) includes a nonlinear time-varying term v₂/v₁, to implement this nonlinear transfer function in the controller, the transfer function is first discretized by using a zero-order hold (ZOH) or bilinear transformation (Tustin), to obtain a difference equation form including coefficients v₂/v₁; and then, the coefficients of the difference equation are updated in each control cycle of the controller.

As shown in FIG. 4B, the transfer function G_{LCFF}(S) of the load-current feedforward path in the high-voltage side voltage control mode of the HMDCT is as follows:

$${G}_{LCFF} ( s ) = 1 + \frac{{C}_{1}}{{C}_{2}} \frac{{L}_{eq} {C}_{2} {s}^{2} + {R}_{eq} {C}_{2} s}{{L}_{eq} {C}_{2} {s}^{2} + {R}_{eq} {C}_{2} s + 1} = 1 + \frac{{L}_{eq} {C}_{1} {s}^{2} + {R}_{eq} {C}_{1} s}{{L}_{eq} {C}_{2} {s}^{2} + {R}_{eq} {C}_{2} s + 1} . \qquad ( 5 )$$

The above formula does not include the nonlinear time-varying term, and therefore, the transfer function is discretized once by directly using the ZOH or the Tustin, without the need to update the coefficients of the difference equation in each cycle.

Step 4: according to a disturbance offset method in feedforward control and by adding the error compensation component ζ* output by the PI controller in step 2, designing the following control strategy, and calculating the reference value of the output current of the PS-DAB:

As shown in FIG. 3C, the control strategy in the low-voltage side voltage control mode of the HMDCT is as follows:

$$〈 {i}_{lP} 〉 * ( s ) = {G}_{PI} ( s ) ( {V}_{l}^{*} ( s ) - {v}_{l} ( s ) ) + {G}_{LCFF} ( s ) {i}_{l} ( s ) = {ζ}^{*} ( s ) + ( 1 - \frac{{v}_{2} / {v}_{1}}{{L}_{eq} {C}_{1 ‖ 2} {s}^{2} + {R}_{eq} {C}_{1 ‖ 2} s + {v}_{2} / {v}_{1}} ) {i}_{l} ( s ) ; \qquad ( 6 )$$

wherein, iₗ(s) is a low-voltage side measured load current value of the HMDCT, ζ*(s) is the error compensation component output by the PI controller G_{PI}(s), and G_{LCFF}(S) is the transfer function of the load-current feedforward path.

As shown in FIG. 4C, the control strategy in the high-voltage side voltage control mode of the HMDCT is as follows:

$$〈 {i}_{hP} 〉 * ( s ) = {G}_{PI} ( s ) ( {V}_{h}^{*} ( s ) - {v}_{h} ( s ) ) + {G}_{LCFF} ( s ) {i}_{h} ( s ) = {ζ}^{*} ( s ) + ( 1 - \frac{{L}_{eq} {C}_{1} {s}^{2} + {R}_{eq} {C}_{1} s}{{L}_{eq} {C}_{2} {s}^{2} + {R}_{eq} {C}_{2} s + 1} ) {i}_{h} ( s ) ; \qquad ( 7 )$$

wherein, iₕ(S) is a high-voltage side measured load current value of the HMDCT, ζ*(s) is the error compensation component output by the PI controller G_{PI}(s), and G_{LCFF}(S) is the transfer function of the load-current feedforward path.

Step 5: calculating the optimal phase shift ratio based on an output current instruction [symbol] i_{lP} [symbol] * or [symbol] i_{hP} [symbol] * (that is, the reference value of the output current of the PS-DAB) of the PS-DAB in step 4, the high-voltage side measured voltage value v₁ of the PS-DAB or the low-voltage side measured voltage value vₗ of the HMDCT in step 1, a switching frequency fₛ of the PS-DAB determined during hardware design of the HMDCT, and inductance Lₖ of the PS-DAB, to obtain the optimal phase shift ratio Dₚ of the PS-DAB.

As shown in FIG. 3A to FIG. 3C, a calculation method for the optimal phase shift ratio Dₚ in the low-voltage side voltage control mode of the HMDCT is as follows:

$${D}_{p} = \frac{1 - \sqrt{1 - \frac{8 \vert {〈 {i}_{lP} 〉}^{*} \vert {f}_{s} {L}_{k}}{{v}_{1} {N}_{PS}}}}{2} sign ( \frac{{〈 {i}_{lP} 〉}^{*}}{{v}_{1}} ) , \frac{{〈 {i}_{lP} 〉}^{*}}{{v}_{1}} \leq \frac{{N}_{PS}}{8 {f}_{s} {L}_{k}} . \qquad ( 8 )$$

As shown in FIG. 4A to FIG. 4C, a calculation method for the optimal phase shift ratio Dₚ in the high-voltage side voltage control mode of the HMDCT is as follows:

$${D}_{p} = \frac{1 - \sqrt{1 - \frac{8 \vert {〈 {i}_{hP} 〉}^{*} \vert {f}_{s} {L}_{k}}{{v}_{l} {N}_{PS}}}}{2} sign ( \frac{{〈 {i}_{hP} 〉}^{*}}{{v}_{l}} ) , \frac{{〈 {i}_{hP} 〉}^{*}}{{v}_{l}} \leq \frac{{N}_{PS}}{8 {f}_{s} {L}_{k}} . \qquad ( 9 )$$

Step 6: performing modulation according to the optimal phase shift ratio Dₚ, generating single-phase shift modulation PWM signals, and sending the wave to the HMDCT; and
controlling and driving, based on the PWM signals, switching components in the HMDCT to perform corresponding switching actions, thereby controlling the HMDCT to quickly respond to the change in the load current in the currently selected control mode, where this control cycle ends.

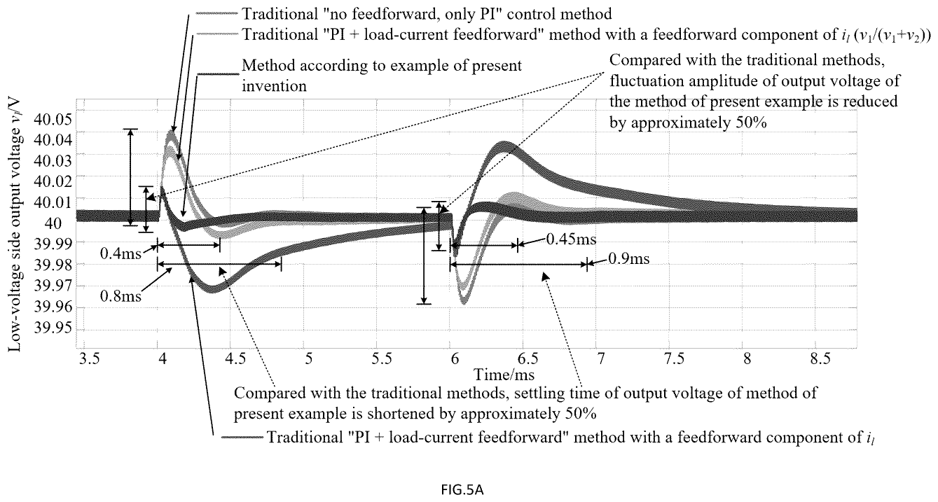

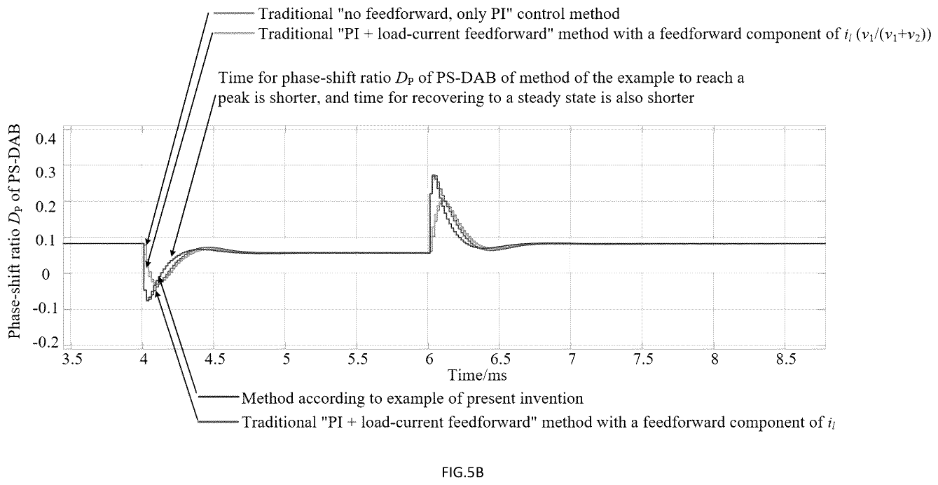

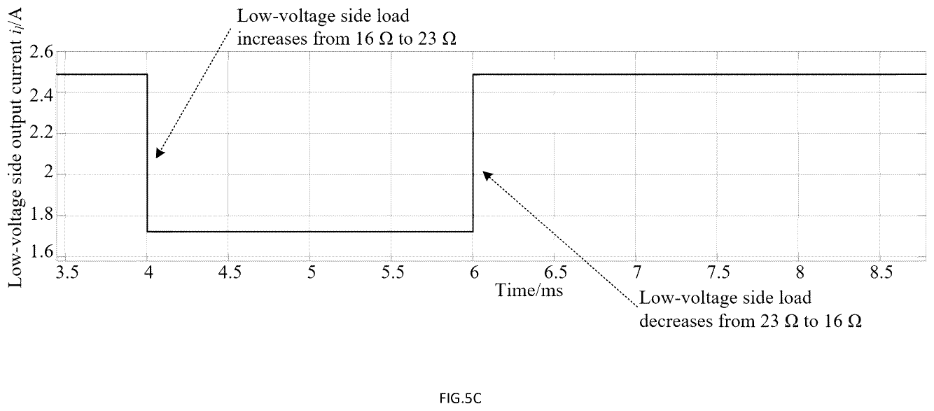

FIG. 5A to FIG. 5C show a comparison of control performance between a control method of the present example and traditional control methods in the low-voltage side voltage control mode of the HMDCT. When the load changes, the control method of the present example provides a faster and more accurate power response of the HMDCT, a smaller overshoot of the low-voltage side output voltage v₁ of the HMDCT, and a more stable output voltage.

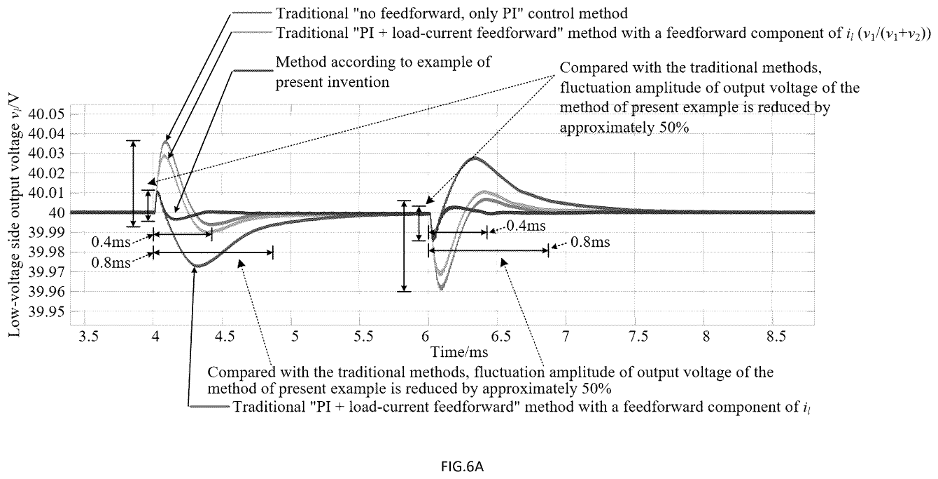

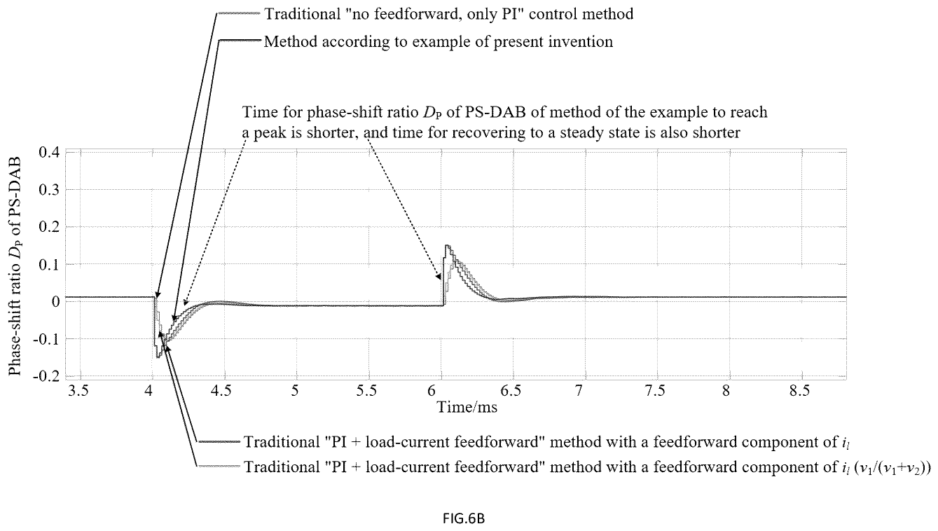

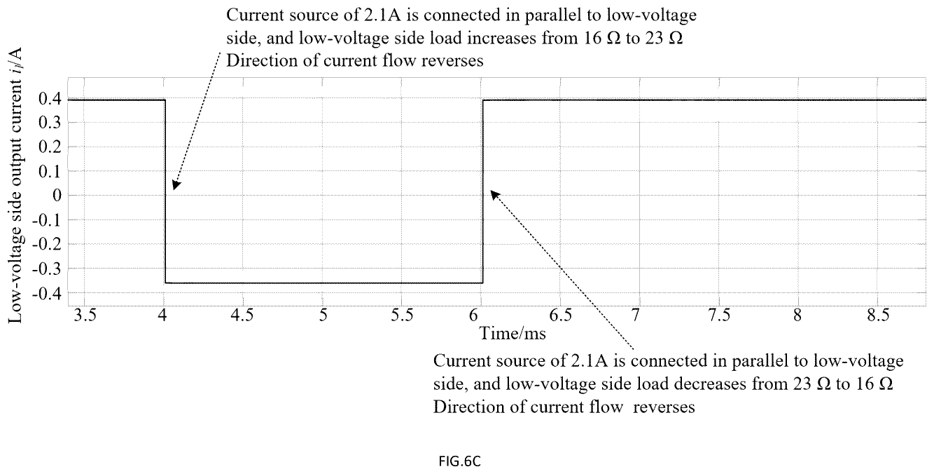

FIG. 6A to FIG. 6C show a comparison of control performance between a control method of the present example and traditional control methods in the low-voltage side voltage control mode of the HMDCT when a load current (power flow) direction reverses. When the load current suddenly reverses, the control method of the present example provides a faster and more accurate power response of the HMDCT, a smaller overshoot of the low-voltage side output voltage vₗ of the HMDCT, and a more stable output voltage.

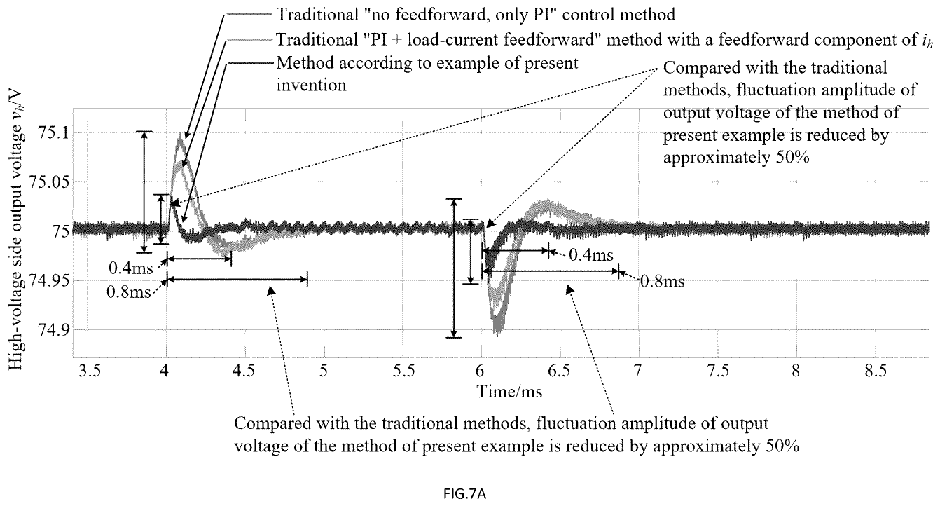

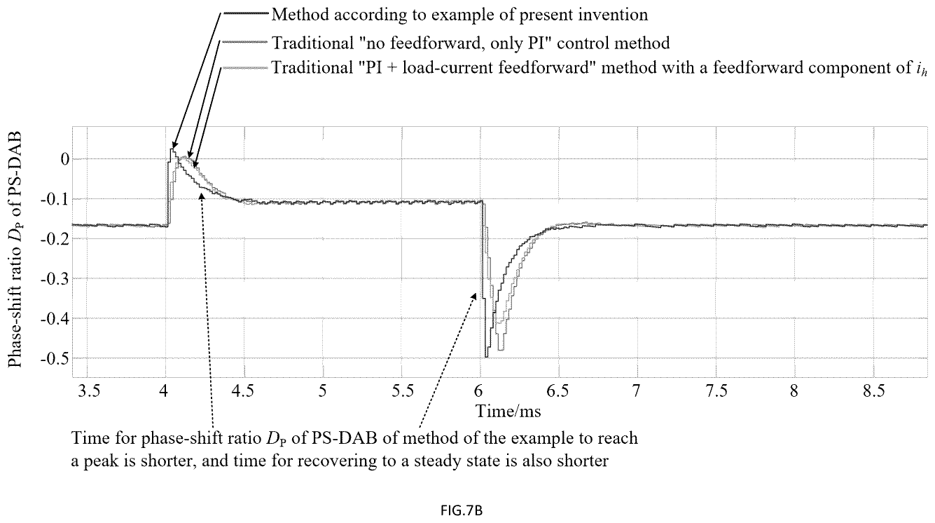

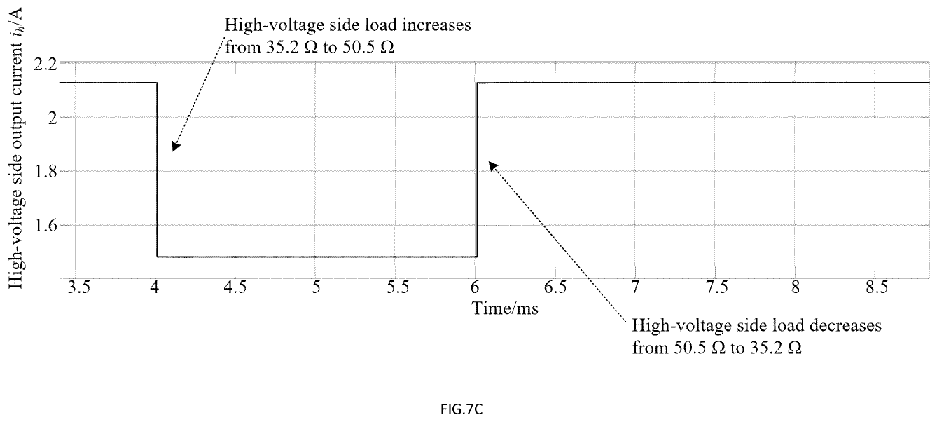

FIG. 7A to FIG. 7C show a comparison of control performance between a control method of the present example and traditional control methods in the high-voltage side voltage control mode of the HMDCT. When the load changes, the control method of the present example provides a faster and more accurate power response of the HMDCT, a smaller overshoot of the high-voltage side output voltage vₕ of the HMDCT, and a more stable output voltage.

### Example 2

An example of the present invention provides a system for controlling a HMDCT based on load-current feedforward, may be quickly responding to a change in a load current for the HMDCT that at least includes one PS-DAB and one SR-DAB, including:
a data real-time acquisition module, configured to: acquire a corresponding measured voltage value and measured current value of the HMDCT according to a currently selected control mode;
an error compensation calculation module, configured to: calculate a difference between the measured voltage value and a voltage reference value, use the difference as a control error, and input the difference into a PI controller, to obtain an error compensation component;
a transfer function construction module, configured to: construct a transfer function of a load-current feedforward path in real time according to a hardware parameter and the measured voltage value of the HMDCT;
a current reference calculation module, configured to: construct an improved feedforward control strategy based on the measured current value, the error compensation component, and the transfer function of the load-current feedforward path, and calculate a reference value of an output current of the PS-DAB in real time; and
a PWM signals generation module, configured to: calculate an optimal phase shift ratio of the PS-DAB according to the reference value of the output current of the PS-DAB, modulate to generate PWM signals according to the optimal phase shift ratio obtained through calculation, and input the wave into the HMDCT; and
control and drive, based on the PWM signals, switching components in the HMDCT to perform corresponding switching actions, thereby controlling the HMDCT to quickly respond to the change in the load current in the currently selected control mode.

### Example 3

An example of the present invention provides a computer program product, including a computer program, wherein when the computer program is executed by a processor, causing the processor to implement the method for controlling the HMDCT based on the load-current feedforward according to Example 1.

### Example 4

An example of the present invention provides a non-transitory computer-readable storage medium, and the non-transitory computer-readable storage medium is configured to store a computer instruction, wherein when the computer instruction is executed by a processor, causing the processor to implement the method for controlling the HMDCT based on the load-current feedforward according to Example 1.

### Example 5

An example of the present invention provides an electronic device, including: a processor, a memory, and a computer program, wherein the processor is connected to the memory, the computer program is stored in the memory, and when the electronic device is operated, the processor executes the computer program stored in the memory, to enable the electronic device to execute the method for controlling the HMDCT based on the load-current feedforward according to Example 1.

The present invention is described with reference to the flowcharts and/or block diagrams of the method, the device (system), and the computer program product according to the examples of the present invention. It should be understood that a computer program instruction may be used to implement each process and/or each block in the flowcharts and/or the block diagrams and a combination of a process and/or a block in the flowcharts and/or the block diagrams. These computer program instructions may be provided to a general-purpose computer, a special-purpose computer, an embedded processor, or a processor of another programmable data processing device to generate a machine, so that the instructions executed by a computer or a processor of any other programmable data processing device generate an apparatus for implementing a specified function in one or more processes in the flowcharts and/or in one or more blocks in the block diagrams.

These computer program instructions may also be loaded onto a computer or another programmable data processing device, so that a series of operation steps are performed on the computer or another programmable device to generate computer-implemented processing. Therefore, the instructions executed on the computer or another programmable device are used to provide steps for implementing a specific function in one or more processes in the flowcharts and/or in one or more blocks in the block diagrams.

Although the above descriptions describe specific implementations of the present invention in conjunction with the accompanying drawings, it is not intended to limit the protection scope of the present invention. Those skilled in the art should understand that various modifications or variations that can be made by those skilled in the art without creative efforts based on the technical solutions of the present invention still fall within the protection scope of the present invention.

1. A method for controlling a hybrid modular direct current transformer (HMDCT) based on load-current feedforward, responding to a change in a load current for the HMDCT comprising at least one phase-shift dual active bridge (PS-DAB) and one series resonant dual active bridge (SR-DAB), wherein specific steps of the method are as follows:
acquiring corresponding measured voltage and current values of the HMDCT according to a selected control mode;
using a difference between the measured voltage value and a reference value thereof as a control error, and inputting the difference into a PI controller, to obtain an error compensation component;
constructing a transfer function of a load-current feedforward path in real time according to a hardware parameter and the measured voltage value of the HMDCT;
constructing an improved feedforward control strategy based on the measured current value, the error compensation component, and the transfer function of the load-current feedforward path, and calculating a reference value of an output current of the PS-DAB in real time; and
calculating an optimal phase shift ratio of the PS-DAB according to the reference value of the output current of the PS-DAB, and modulating to generate PWM signals for controlling the HMDCT in the mode, wherein
the transfer function of the load-current feedforward path is specifically as follows:
if the HMDCT is required to work in a low-voltage side voltage control mode, the transfer function of the load-current feedforward path is as follows:
$${G}_{LCFF} ( s ) = 1 - \frac{{v}_{2} / {v}_{1}}{{L}_{eq} {C}_{1 ‖ 2} {s}^{2} + {R}_{eq} {C}_{1 ‖ 2} s + 1 + {v}_{2} / {v}_{1}} ;$$
wherein, s is a complex frequency variable in the transfer function, v₁ and v₂ are a high-voltage side measured voltage value of the PS-DAB and a high-voltage side measured voltage value of the SR-DAB in a current working state of the HMDCT, C_{1∥2} is a sum of capacitance values of a high-voltage side capacitor C₁ of the PS-DAB and a high-voltage side capacitor C₂ of the SR-DAB, and L_{eq} and R_{eq} are equivalent direct current (DC) inductance and resistance respectively; and
if the HMDCT is required to work in a high-voltage side voltage control mode, the transfer function of the load-current feedforward path is as follows:
$${G}_{LCFF} ( s ) = 1 + \frac{{C}_{1}}{{C}_{2}} \frac{{L}_{eq} {C}_{2} {s}^{2} + {R}_{eq} {C}_{2} s}{{L}_{eq} {C}_{2} {s}^{2} + {R}_{eq} {C}_{2} s + 1} = 1 + \frac{{L}_{eq} {C}_{1} {s}^{2} + {R}_{eq} {C}_{1} s}{{L}_{eq} {C}_{2} {s}^{2} + {R}_{eq} {C}_{2} s + 1} .$$

2. The method for controlling the HMDCT based on the load-current feedforward according to claim 1, wherein the control mode comprises the low-voltage side voltage control mode and the high-voltage side voltage control mode;
if the HMDCT is required to work in the low-voltage side voltage control mode, the corresponding measured voltage and current values of the HMDCT are: a high-voltage side voltage of the PS-DAB, a high-voltage side voltage of the SR-DAB, a low-voltage side output voltage of the HMDCT, and a low-voltage side load current of the HMDCT, and a difference between the low-voltage side output voltage of the HMDCT and a reference value thereof is used as the control error; and
if the HMDCT is required to work in the high-voltage side voltage control mode, the corresponding measured voltage and current values of the HMDCT are: a high-voltage side voltage of the PS-DAB, a high-voltage side voltage of the SR-DAB, a low-voltage side input voltage of the HMDCT, and a high-voltage side load current of the HMDCT, and a difference between a high-voltage side measured voltage value and a reference value thereof is used as the control error, wherein the high-voltage side measured voltage value is a sum of the high-voltage side voltage of the PS-DAB and the high-voltage side voltage of the SR-DAB.

3. The method for controlling the HMDCT based on the load-current feedforward according to claim 1, wherein the error compensation component is specifically as follows:
if the HMDCT is required to work in the low-voltage side voltage control mode, using the PI controller to calculate the error compensation component, which is represented by a formula as follows:
$${ζ}^{*} ( s ) = {G}_{PI} ( s ) ( {V}_{l}^{*} ( s ) - {v}_{l} ( s ) ) ;$$
wherein, s is the complex frequency variable in the transfer function, G_{PI}(s) represents the PI controller, and v₁ and
$${V}_{l}^{*}$$
are a low-voltage side measured voltage value and a reference value thereof, respectively; and
if the HMDCT is required to work in the high-voltage side voltage control mode, using the PI controller to calculate the error compensation component, which is represented by a formula as follows:
$${ζ}^{*} ( s ) = {G}_{PI} ( s ) ( {V}_{h}^{*} ( s ) - {v}_{h} ( s ) ) ;$$
wherein, s is the complex frequency variable in the transfer function, G_{PI} represents the PI controller, and vₕ and
$${V}_{h}^{*}$$
are a high-voltage side measured voltage value and a reference value thereof, respectively.

4. The method for controlling the HMDCT based on the load-current feedforward according to claim 1, wherein the improved feedforward control strategy is specifically as follows:
if the HMDCT is required to work in the low-voltage side voltage control mode, a control strategy for calculating the reference value of the output current of the PS-DAB is as follows:
$$〈 {i}_{lP} 〉 * ( s ) = {G}_{PI} ( s ) ( {V}_{l}^{*} ( s ) - {v}_{l} ( s ) ) + {G}_{LCFF} ( s ) {i}_{l} ( s ) = {ζ}^{*} ( s ) + ( 1 - \frac{{v}_{2} / {v}_{1}}{{L}_{eq} {C}_{1 ‖ 2} {s}^{2} + {R}_{eq} {C}_{1 ‖ 2} s + {v}_{2} / {v}_{1}} ) {i}_{l} ( s ) ;$$
wherein, iₗ(s) is a low-voltage side measured load current value of the HMDCT, ζ*(s) is the error compensation component output by the PI controller G_{PI}(s), and G_{LCFF}(S) is the transfer function of the load-current feedforward path in the low-voltage side voltage control mode; and
if the HMDCT is required to work in the high-voltage side voltage control mode, a control strategy for calculating the reference value of the output current of the PS-DAB is as follows:
$$〈 {i}_{hP} 〉 * ( s ) = {G}_{PI} ( s ) ( {V}_{h}^{*} ( s ) - {v}_{h} ( s ) ) + {G}_{LCFF} ( s ) {i}_{h} ( s ) = {ζ}^{*} ( s ) + ( 1 + \frac{{L}_{eq} {C}_{1} {s}^{2} + {R}_{eq} {C}_{1} s}{{L}_{eq} {C}_{2} {s}^{2} + {R}_{eq} {C}_{2} s + 1} ) {i}_{h} ( s ) ;$$
wherein, iₕ(S) is a high-voltage side measured load current value of the HMDCT, ζ*(s) is the error compensation component output by the PI controller G_{PI}(s), and G_{LCFF}(S) is the transfer function of the load-current feedforward path in the high-voltage side voltage control mode.

5. The method for controlling a HMDCT based on load-current feedforward according to claim 4, wherein a calculation method for the optimal phase shift ratio is as follows:
if the HMDCT is required to work in the low-voltage side voltage control mode, the calculation method for the optimal phase shift ratio Dₚ is as follows:
$${D}_{p} = \frac{1 - \sqrt{1 - \frac{8 \vert {〈 {i}_{lP} 〉}^{*} \vert {f}_{s} {L}_{k}}{{v}_{1} {N}_{PS}}}}{2} sign ( \frac{{〈 {i}_{lP} 〉}^{*}}{{v}_{1}} ) , \frac{{〈 {i}_{lP} 〉}^{*}}{{v}_{1}} \leq \frac{{N}_{PS}}{8 {f}_{s} {L}_{k}} ;$$
wherein, v₁ is the high-voltage side measured voltage value of the PS-DAB, fₛ is a switching frequency of the PS-DAB, Lₖ is inductance of the PS-DAB, and [symbol] i_{lP} [symbol] , is the reference value of the output current of the PS-DAB; and
if the HMDCT is required to work in the high-voltage side voltage control mode, the calculation method for the optimal phase shift ratio Dₚ is as follows:
$${D}_{p} = \frac{1 - \sqrt{1 - \frac{8 \vert {〈 {i}_{hP} 〉}^{*} \vert {f}_{s} {L}_{k}}{{v}_{l} {N}_{PS}}}}{2} sign ( \frac{{〈 {i}_{hP} 〉}^{*}}{{v}_{l}} ) , \frac{{〈 {i}_{hP} 〉}^{*}}{{v}_{l}} \leq \frac{{N}_{PS}}{8 {f}_{s} {L}_{k}} ;$$
wherein, vₗ is a low-voltage side measured voltage value of the HMDCT, fₛ is a switching frequency of the PS-DAB, Lₖ is inductance of the PS-DAB, and [symbol] i_{hP} [symbol] * is the reference value of the output current of the PS-DAB.

6. A system for controlling a hybrid modular direct current transformer (HMDCT) based on load-current feedforward, adopting the method for controlling the HMDCT based on the load-current feedforward according to claim 1, responding to the change in the load current for the HMDCT comprising at least one PS-DAB and one SR-DAB, and the system comprising:
a data real-time acquisition module, configured to: acquire corresponding measured voltage and current values of the HMDCT according to a selected control mode;
an error compensation calculation module, configured to: use a difference between the measured voltage value and a reference value thereof as a control error, and input the difference into a PI controller, to obtain an error compensation component;
a transfer function construction module, configured to: construct a transfer function of a load-current feedforward path in real time according to a hardware parameter and the measured voltage value of the HMDCT;
a current reference calculation module, configured to: construct an improved feedforward control strategy based on the measured current value, the error compensation component, and the transfer function of the load-current feedforward path, and calculate a reference value of an output current of the PS-DAB in real time; and
a PWM signals generation module, configured to: calculate an optimal phase shift ratio of the PS-DAB according to the reference value of the output current of the PS-DAB, and modulate to generate PWM signals for controlling the HMDCT in the mode.

7. A computer program product, comprising a computer program, wherein when the computer program is executed by a processor, causing the processor to implement the method for controlling the HMDCT based on the load-current feedforward according to claim 1.

8. A non-transitory computer-readable storage medium, wherein the non-transitory computer-readable storage medium is configured to store a computer instruction, and when the computer instruction is executed by a processor, causing the processor to implement the method for controlling the HMDCT based on the load-current feedforward according to claim 1.

9. An electronic device, comprising: a processor, a memory, and a computer program, wherein the processor is connected to the memory, the computer program is stored in the memory, and when the electronic device is operated, the processor executes the computer program stored in the memory, to enable the electronic device to execute and implement the method for controlling the HMDCT based on the load-current feedforward according to claim 1.
